(19) United States
(12) Patent Application Publication
(10) Pub. No.: US 2010/0187568 A1
(43) Pub. Date: Jul. 29, 2010

(54) EPITAXIAL METHODS AND STRUCTURES FOR FORMING SEMICONDUCTOR MATERIALS

(75) Inventor: Chantal ARENA, Mesa, AZ (US)

Correspondence Address: TRASKBRITT, P.C., P.O. BOX 2550, SALT LAKE CITY, UT, 84110, US

(73) Assignee: S.O.I.TEC SILICON ON INSULATOR TECHNOLOGIES, S.A., Bernin (FR)

(21) Appl. No.: 12/610,092

(22) Filed: Oct. 30, 2009

Related U.S. Application Data
(60) Provisional application No. 61/147,881, filed on Jan. 28, 2009.

(51) Int. Cl. H01L 29/20; H01L 21/20

(52) U.S. Cl. 257/190; 438/478; 257/E21.09; 438/692; 257/E21.214; 257/E29.089

(57) ABSTRACT

Methods and structures for producing semiconductor materials, substrates and devices with improved characteristics are disclosed. Structures and methods for forming reduced strain structures include forming a plurality of substantially strain-relaxed island structures and utilizing such island structures for subsequent further growth of strain-relaxed substantial continuous layers of semiconductor material.

### CROSS-REFERENCE TO RELATED APPLICATION

This application claims benefit under 35 U.S.C. §119(e) of U.S. Provisional Application No. 61/147,881 filed Jan. 28, 2009, which is incorporated herein by reference.

### FIELD OF THE INVENTION

The various embodiments of the present invention generally relate to the fabrication of semiconductor structures and substrates. The various embodiments provide methods and structures for producing semiconductor materials and substrates with improved characteristics.

### BACKGROUND OF THE INVENTION

Strained layers of semiconductor materials can be undesirable for a number of reasons. Strain in the semiconductor layers can result in an increased density of defects, crack formation and phase separation, in broad terms, a possible reduction in material quality.

Strain effects can be disadvantageous in fabricating III-V semiconductor materials such as the III-nitrides. For example, consider III-nitride based light emitting devices containing indium gallium nitride (InₓGa₁₋ₓN) with significant indium content (e.g., x>0.15). The increased indium content preferred in such devices, for extending the emission wavelength range, commonly introduces disadvantageous levels of strain due to lattice mismatch with adjoining layers. The strained layers commonly have restricted thicknesses and low indium content in an attempt to prevent material phase separation and subsequent non-uniform indium distribution.

In more detail, the binary components of the compound InGaN, namely InN and GaN are not fully miscible and therefore under a given set of growth conditions and film thickness there is a fixed range of energetically favorable InGaN compositions. The introduction of lattice strain and defects into the InGaN system can result in thicker InGaN layers grown at energetically unfavorable compositions tending to phase separate i.e., the material is no longer of a single composition and the In and Ga atoms will not be homogenously distributed throughout the layer. The non-homogeneity in the InGaN material can result in a deterioration of the efficiency of III-nitride based devices.

Therefore, prior art approaches can be impractical for achieving material goals relating to substantially single phase, strain-relaxed materials with desired compositions. As a result, methods and structures are desired for producing strain free, single phase semiconductor layers.

U.S. Pat. No. 7,271,416, which issued Sep. 18, 2007 to Saxler, discloses semiconductor structures and methods of fabricating semiconductor structures for reducing strain in adjacent material layers. As disclosed therein, a semiconductor structure may include a substrate having a first in-plane unstrained lattice constant, a first layer of semiconductor material on the substrate having a second in-plane unstrained lattice constant that is different from the first in-plane unstrained lattice constant, and a variable mismatch layer comprising a second semiconductor material disposed between the substrate and the first layer of semiconductor material. The variable mismatch layer is configured to reduce stress in the first layer to below a level of stress resulting from growth of the first layer directly on the substrate. The variable mismatch layer may be a layer having a strained in-plane lattice constant that substantially matches the unstrained lattice constant of the first layer.

U.S. patent application Ser. No. 11/237,164, which was filed Sep. 27, 2005 by Krames et al. (U.S. Patent Application Publication No. 2007/0072324 A1, published Mar. 29, 2007), discloses an engineered substrate for growing a light emitting device that includes a host substrate and a seed layer bonded to the host substrate. A semiconductor structure including a light emitting layer disposed between an n-type region and a p-type region is grown on the seed layer. A bonding layer may be used to bond the host substrate to the seed layer. The seed layer may be thinner than a critical thickness for relaxation of strain in the semiconductor structure, such that strain in the semiconductor structure is relieved by dislocations formed in the seed layer, or by gliding between the seed layer and the bonding layer. The host substrate may be separated from the semiconductor structure and seed layer by etching away the bonding layer.

Semiconductor layers grown heteroepitaxially to an underlying substrate may be undesirably strained due to lattice mismatch between the dissimilar layers. The composition of semiconductor layers can therefore be restricted and the quality impacted. Methods and structures for providing semiconductor layers with reduced strain and preferred compositions are therefore desirable.

### SUMMARY OF THE INVENTION

The various embodiments of the present invention generally provide methods and structures for fabricating semiconductor layers with high crystal quality. The methods are now briefly described in terms of certain embodiments of the invention. This summary is provided to introduce a selection of concepts in a simplified form that are further described in the detailed description of the embodiments of the invention. This summary is not intended to identify key features or essential features of the claimed subject matter, nor is it intended to be used to limit the scope of the claimed subject matter.

The embodiments of the invention are concerned with the formation of substantially continuous films of semiconductor material (e.g., III-nitrides) which have improved material characteristics, namely a reduced density of defects/dislocation, substantially strain-relaxed (i.e., reduced levels of lattice strain) and substantially free of phase separation (e.g., an InGaN material of a single composition).

To enable formation of such semiconductor materials, embodiments of the invention involve the formation of randomly arranged and separated island like structures of semiconductor material (e.g., InGaN) having upper regions with desirable crystal characteristics, i.e., strain free, of a single composition and with a desirable defect (e.g., dislocation) density. However, separate randomly arranged island structures of high quality material are not practically useful for the formation of substrates or device structures etc., due to their random nature and small dimensions.

Therefore, the various embodiments of the invention utilize the separate randomly arranged island structures of high quality material as seed crystals for performing further growth. Further growth processes are utilized for the formation of substantially continuous layers of semiconductor materials. The island like structures are utilized as seeds crystals for further epitaxial growth processes, the various growth processes producing continuous layers of high quality semiconductor material.

In a first embodiment the high quality relaxed island structures are used directly as seed crystals for further growth, without employing any further masking structures, lateral growth techniques etc. Embodiments therefore continue with further growth from the island structures, wherein further growth increases the size of the island structures substantially uniformly, i.e., isotropically, with somewhat uniform increase in size along all facets (e.g., in both lateral and vertical directions) until such time as the island structure coalesce to form a substantially continuous layer of semiconductor material.

In certain embodiments upon coalescence the growth mode of the semiconductor structure can be altered to grow more preferentially in a vertical direction. In additional embodiments the surface of the high quality substantially continuous semiconductor layer produced may require smoothing to remove any residual surface roughness from the layer to enable subsequent processing, such as device formation, layer transfer etc. Smoothing of the layer can be achieved via etching, mass transport regrowth, polishing/grinding methods etc.

Alternative, methods are known in the art to produce continuous layers of material from separated seed crystals, such as island structures. Methods such as epitaxial lateral overgrowth (ELO) and its many variants (e.g., FIELO, PENDEO etc.) are known in the art as techniques for bridging the gap between individual separated seed crystals to produce a continuous layer of material. However, methods are not known, at this time, to enable lateral growth of certain semiconductor materials, such as certain InGaN material compositions, as InGaN has proven a complex material to grow in a lateral mode.

Therefore embodiments of the invention perform lateral growth (to form lateral growth regions) from the high quality semiconductor island structures (e.g., InGaN) utilizing materials capable of substantial lateral growth, for example materials such as GaN (or low indium content InGaN), as methods for GaN lateral growth to form continuous layers are known in the art.

To prevent strain relaxation in the lateral growth regions, the thickness of the regions is maintained at or below the critical thickness, and, as a result, the lateral growth regions are strained and maintain the in-plane lattice parameter of the high quality island structures, whilst preventing the formation of additional defects/dislocation by preventing strain relaxation.

Methods of the invention may therefore produce a template structure which comprises an upper continuous surface which has an in-plane lattice parameter substantially equal to the lattice parameter of the relaxed upper surface of the island structures (e.g., InGaN), whilst maintaining a preferred defect/dislocation density. Such a template structure of semiconductor material with preferred material characteristics is highly suitable for the growth of further high quality continuous semiconductor layers, for example for the growth of InGaN material with an indium content substantially similar or greater than that of the underlying InGaN island structures.

Therefore the embodiments of the invention provide methods for forming semiconductor structures. The embodiments of the invention include forming a plurality of randomly arranged island structures with a first material composition and performing a further growth from the island structures, the composition of the further growth having a second material composition. In addition, a vertical growth is performed to form a vertical growth layer, the composition of the vertical growth layer having a third material composition.

Further embodiments of the invention include forming the island structures by epitaxial growth on a lattice mismatched base substrate and in certain embodiments forming a masking structure on the base substrate so that the upper portions of the island structures are exposed through the masking structure.

The randomly arranged island structures can comprise regions which are strain-relaxed and further growth can substantially originate from these strain-relaxed portions of the island structures. In additional embodiments, the further growth from the island structures forms isotropic growth regions. In such embodiments, chemical mechanical polishing of the isotropic growth regions or the resulting vertical growth regions may be necessary.

In alternative embodiments, the further growth from the island structures forms lateral growth regions, wherein lateral growth can originate substantially from the upper surface of the island structures or substantially from the side facets of the island structures. The thickness of the lateral growth regions may be maintained at or below the critical thickness of the lateral growth regions, i.e., at or below the thickness at which further defects/dislocations are formed.

The first, second and third material compositions may comprise III-nitride material and further may comprise InₓGa₁₋ₓN. In certain embodiments the second material composition may comprise GaN and the first and third material compositions can be substantially equal.

The masking structure on the base substrate can be formed by deposition of one or more dielectric materials followed by the subsequent removal of a portion of the masking structure, such a removal process can be performed utilizing chemical mechanical polishing or reactive ion etching methods.

The various embodiments of the invention also include semiconductor structures formed during the processes previously outlined. The semiconductor structures can comprise a plurality of randomly arranged island structures upon a lattice mismatched base substrate, a further growth region and a vertical growth layer.

The randomly arranged island structures can be substantially strain-relaxed and further one or more dielectric masking materials can be formed to substantially cover the exposed portions of the base substrate.

The further growth regions in certain embodiments comprise lateral growth regions at a thickness equal to or less than the critical thickness for the on-set of strain relaxation via the formation of further defects/dislocation. In addition the further growth regions may comprise lateral growth regions which can be formed to produce a substantially continuous layer of material which is below the critical thickness for the on-set of strain relaxation via defect formation.

In certain embodiments the composition of the island structures comprises InₓGa₁₋ₓN with an indium composition greater than x=0.02 and the further growth regions comprises InₓGa₁₋ₓN with an indium composition less than x=0.11, whereas the vertical growth layer can comprise InₓGa₁₋ₓN with an indium composition greater than x=0.02.

Further aspects and details and alternate combinations of the elements of this invention will be apparent from the following detailed description and are also within the scope of the inventor's invention.

### BRIEF DESCRIPTION OF THE DRAWINGS

The present invention may be understood more fully by reference to the following detailed description of the embodiments of the present invention, illustrative examples of specific embodiments of the invention and the appended figures in which:

FIGS. 1 A-F schematically illustrate specific embodiments of the invention for reducing the level of strain in semiconductor structures.

FIG. 2 A-G schematically illustrates further embodiments of the invention for reducing the level of strain in semiconductor structures.

FIG. 3 A-E schematically illustrates additional embodiments of the invention for reducing the level of strain in semiconductor structures.

FIG. 4 A-E schematically illustrates yet further embodiments of the invention for reducing the level of strain in semiconductor structures.

FIG. 5 represents a typical scanning electron microscopy (SEM) image produced from semiconductor structures realized using embodiments of the invention.

FIG. 6 A-C represents typical cross section transmission electron microscopy (TEM) images produced from semiconductor structures realized using embodiments of the inventions.

### DETAILED DESCRIPTION OF THE PREFERRED EMBODIMENT

The illustrations presented herein are not meant to be actual views of any particular material, apparatus, system, or method, but are merely idealized representations which are employed to describe the present invention.

The embodiments of the invention relate to the formation of substantially continuous films of semiconductor material having improved material characteristics. The following description commences with a brief summary of embodiments of the invention followed by a more detailed description.

The term “substantially” is used herein to refer to a result that is complete except for the deficiencies normally expected in the art. For example, an epitaxial layer cannot routinely be expected to be completely continuous (or completely monocrystalline, or completely of one crystal polarity, or completely of single compositional phase) across macroscopic dimensions. However, an epitaxial layer can routinely be expected to be “substantially continuous” (or “substantially monocrystalline”, or “substantially of one crystal polarity”, or “substantially of a single compositional phase”) across macroscopic dimensions where the discontinuities (or crystal domains, or crystal boundaries) present are those expected in the art for the processing conditions, the material quality sought, and so forth.

The term “further growth” refers to the additional epitaxial growth of material or regions of material on preformed island structures.

The term “lateral growth” refers to growth in which the growth direction is predominately in a direction parallel to a surface of a base substrate upon which growth is performed, and the term “lateral growth regions” refers to regions of material grown in such a direction.

The term “vertical growth” refers to growth in which the growth direction is predominately in a direction perpendicular to a surface of a base substrate upon which growth is performed, and the term “vertical growth layer” refers to a layer of material grown in such a direction.

The term “isotropic growth” refers to material growth that is substantially uniform in all directions, although it should be understood that different crystal planes or facets may promote growth at different rates.

The term “critical thickness” refers to a thickness at which strain is sufficient in an epitaxial layer to cause defect formation to reduce the level of strain in the layer.

The term “randomly arranged” refers to an arrangement that, when considered as a whole, is without an identifiable pattern, i.e., without uniformity or regularity.

As used herein, the term “lattice strain”, when used with respect to a layer of material, means strain of the crystal lattice in directions at least substantially parallel to the plane of the layer of material. Similarly, the term “average lattice parameter,” when used with respect to a layer of material, means the average lattice parameter in dimensions at least substantially parallel to the plane of the layer of material.

As used herein, the term “strain-relaxed” or “free of strain”, refers to a crystalline material in which the lattice parameter is substantially equal to an equilibrium lattice parameter of the material.

The embodiments have applications to epitaxially growing a wide range of semiconductor materials and combinations thereof, both elemental semiconductors and compound semiconductors. For example, it can be applied to combinations of Si (silicon) and/or Ge (germanium). It can also be applied to groups II-VI and groups III-V compound semiconductor materials. Particular applications are to growing pure or mixed nitrides of the group III metals (III-nitrides) (e.g., GaN, InGaN, AlGaN, etc.) with reduced levels of strain.

However, for conciseness and convenience of the following description and without intended limitation, the invention is described herein primarily in embodiments directed to growing III-nitrides, and particularly in embodiments directed to forming InGaN materials. This descriptive focus is only for example, and it should not be taken as limiting the invention. In fact, as will be apparent from the subsequent description and appended figures, the methods of the embodiments can readily be applied to growing group III-V compound semiconductors generally, to growing compound semiconductors belonging to other groups (e.g., group II-VI), and to growing elemental and alloy semiconductors. Therefore, it is without limitation that the description herein focuses primarily on embodiments of the invention directed to III-nitrides and specifically to InGaN.

Headings are used herein for clarity only and without any intended limitation. A number of references are cited herein, the entire disclosures of which are incorporated herein, in their entirety, by reference for all purposes. Further, none of the cited references, regardless of how characterized above, is admitted as prior art relative to the invention of the subject matter claimed herein.

Briefly, methods of the invention begin with the formation of a nucleation layer on the surface of a base substrate. Upon formation of the nucleation layer on the base substrate, a plurality of island structures are formed having preferred characteristics. In embodiments of the invention, the island structures may be formed using epitaxial growth methods such that the strain produced due to lattice mismatch between the material of the island structures and that of the base substrate is rapidly relieved (i.e., in a relatively short distance from the surface of the base substrate on which the island structures are formed) such that the majority of the island structures are free of strain (i.e., the island structures are substantially strain-relaxed). For example, lattice mismatch between the material of the island structures and the base substrate may be relieved within the first few atomic layers of growth, and, therefore, the majority of the island structures are free of strain (i.e., have strain-relaxed characteristics).

Upon formation of the island structures, the various embodiments of the invention utilize the separate randomly arranged island structures of high quality material as seed crystals for the formation of substantially continuous layers of semiconductor materials.

In a first embodiment, the high quality relaxed island structures are used directly as seed crystals by continuing further growth from the island structures, thereby increasing the size of the island structures substantially uniformly (i.e., isotropically), with somewhat uniform increase in size along all facets (e.g., in both lateral and vertical directions) until such time as the island structures coalesce to form a substantially continuous layer of semiconductor material.

Upon coalescence, the growth mode of the semiconductor layer can be altered to grow more preferentially in a vertical direction. In additional embodiments, the surface of the isotropically grown material and/or the high quality substantially continuous semiconductor layer produced may be smoothed or planarized to remove any residual surface roughness from the layer to enable subsequent processing, such as device formation, layer transfer, etc. Smoothing of the layer can be achieved via etching, mass transport regrowth, polishing methods, grinding methods, etc.

In further embodiments, upon formation of substantially strain-relaxed island structures, a masking material is applied to cover the island structures and the previously exposed regions of the base substrate. After formation of the masking material, a planarization process is performed to reveal or expose the upper most portions of the island structures whilst maintaining the lower regions of the island structures covered with the masking material. Since the relaxation in the island structures takes places very rapidly during the growth process used to form the island structures, the portions of the island structures proximate the base substrate in which strain may still be present remain covered by the masking material and unavailable for material growth thereon in subsequent process stages. In alternative embodiments of the invention, the masking material may be omitted.

Additional embodiments of the invention utilize the substantially strain-relaxed island structures as nucleation sites for further material growth. In such embodiments, the growth mode may be carried out in a lateral growth mode (forming lateral growth regions) by, for example, utilizing the known process of epitaxial lateral overgrowth (ELO) and its variants. In such embodiments, a material that can be readily grown in a substantially lateral mode may be selected. As a non-limiting example, gallium nitride and indium gallium nitride (with a low indium content) are both materials known to be capable of lateral growth.

The lateral growth material forms lateral growth regions. In certain embodiments, the material compositions of the island structures and the lateral growth regions may be dissimilar and, therefore, a lattice strain can be produced due to lattice mismatch between the island structures and the lateral growth regions. Therefore, in certain embodiments, the thickness of the lateral growth regions may be maintained at or below a critical thickness at which further defects and dislocations form within the crystal structures to relieve the lattice strain. Therefore, in such embodiments, the lattice parameter of the relaxed island structures is substantially maintained in the lateral growth regions, and the relaxed lattice parameter of the upper portions of the island structures is inherited by the lateral growth regions.

Certain embodiments of the invention continue the lateral growth of lateral growth regions until the crystal growth fronts or the growing individual crystals, which originate from the substantially strain-relaxed portions of the separate island structures, intercept and coalesce to form a substantially continuous lateral growth layer which, in certain embodiments, is at or below the critical thickness. The thickness of the lateral growth layer may be in part dependent on both the compositions of the lateral growth layer and the island structures.

In alternative embodiments, the lateral growth regions are produced between the island structures themselves by lateral growth nucleation from side facets of the island structures, thereby producing a layer comprising island structures interposed between lateral growth regions. In such embodiments, lateral growth is nucleated directly from the side facets of the island structures, thereby preserving the high quality crystal structure of the island structures in the lateral growth regions.

Therefore, various embodiments of the invention produce an intermediate structure that comprises an upper continuous surface having an in-plane lattice parameter substantially equal to an in-plane lattice parameter of the upper surfaces of the relaxed island structures, whilst maintaining a desirable defect (e.g., dislocation) density. Such a template structure of semiconductor material with preferred material characteristics is suitable for the growth of further high quality continuous layers of InGaN material (or other III-nitrides) with an indium content substantially similar or greater than that of the InGaN island structures.

Upon formation of such an intermediate structure (e.g., a coalesced lateral growth layer), the growth mode can be altered to progress in a more vertical growth mode to form a vertical growth layer, and vertical growth may be carried out until the semiconductor material exhibits a desired thickness.

In some embodiments, the material composition of the vertical growth layer can be substantially similar to that of the island structures. Since the lattice parameter of the strain-relaxed upper portions of the island structures is maintained through the lateral growth regions (or layer), the strain-relaxed lattice parameter is in turn inherited by the vertical growth layer, and lattice mismatch between the vertical growth layer and the lateral growth regions (or layer) may be avoided, thereby reducing strain and the on-set of phase separation. Therefore, certain embodiments of the invention produce a substantially continuous strain-relaxed layer of InGaN material.

In further embodiments, the material composition of the vertical growth layer can be dissimilar to that of the island structures. For example, the indium content of the vertical growth layer can be increased relative to the indium content in the island structures. In such embodiments, the vertical growth layer can be somewhat strained, however the strain level may be reduced relative to structures known in the prior art, due to the strained lattice parameter of the underlying material.

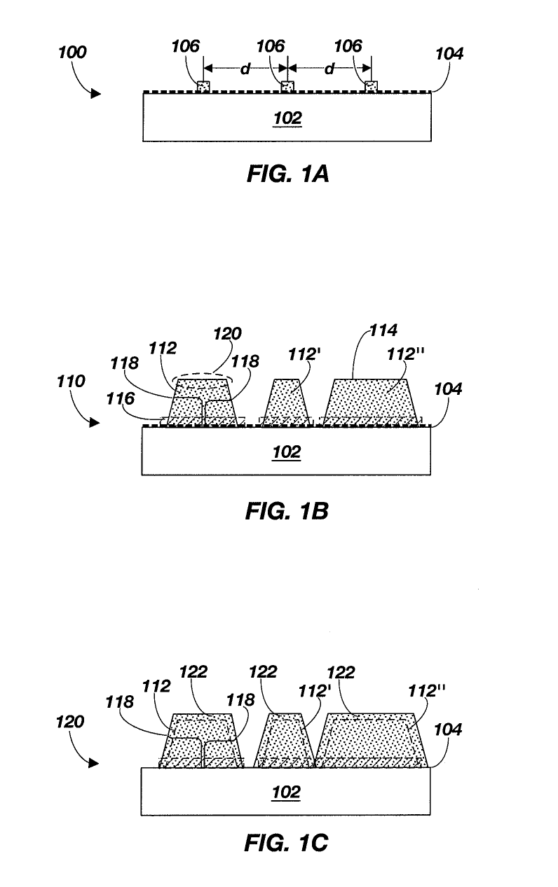

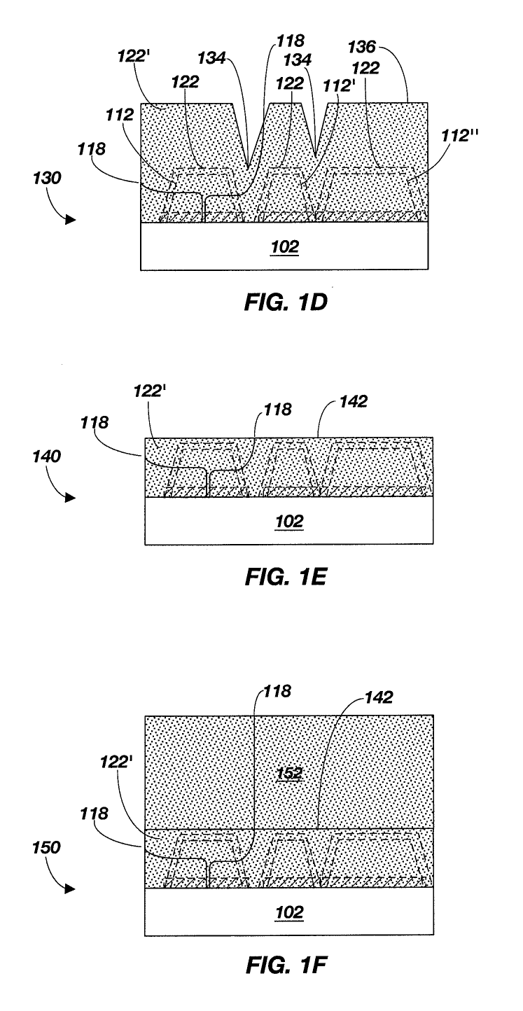

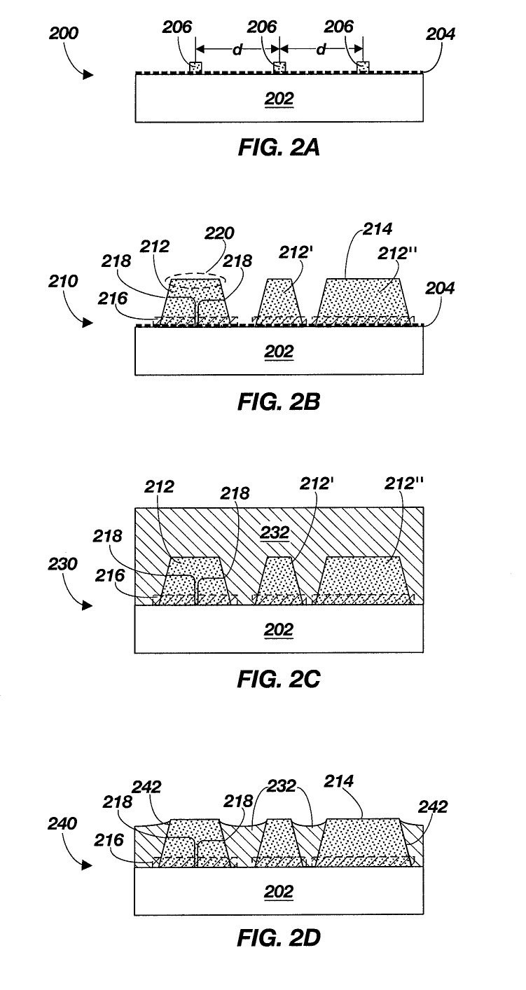

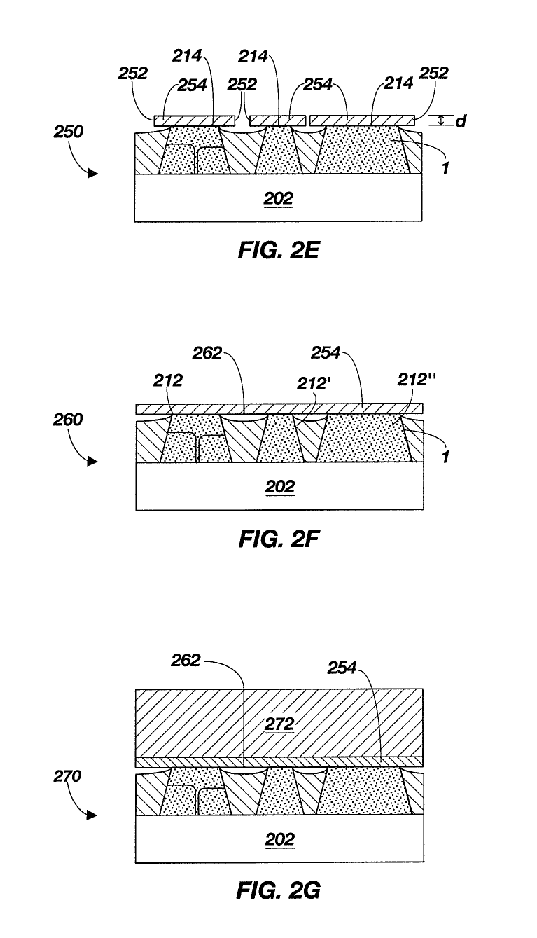

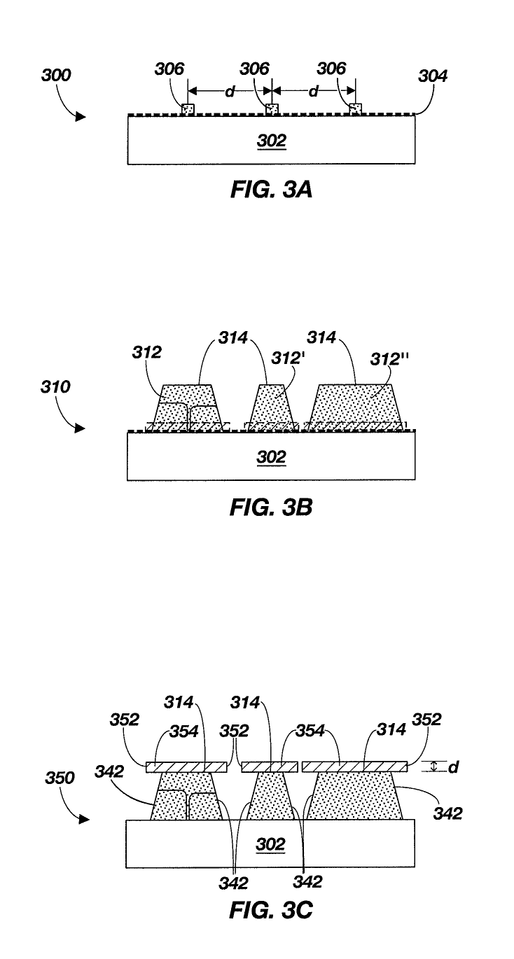

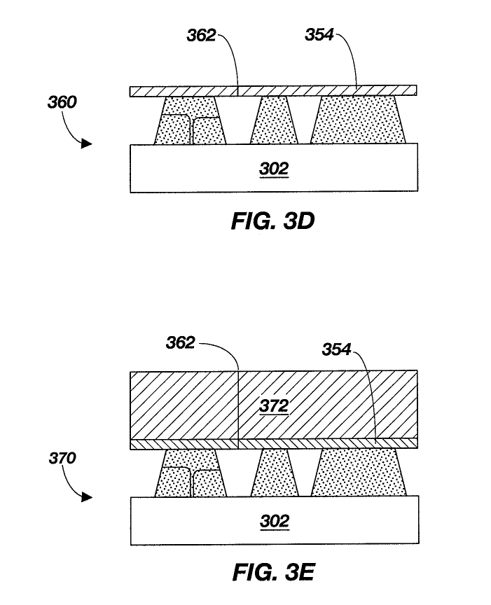

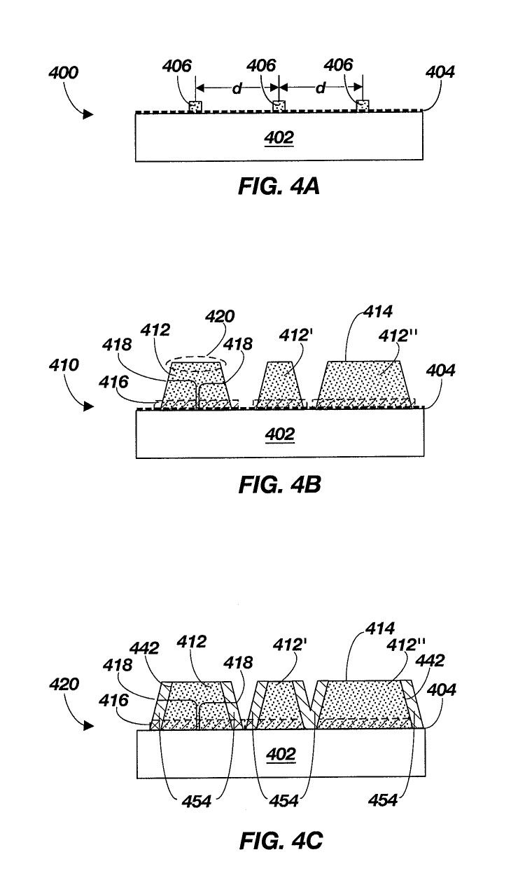

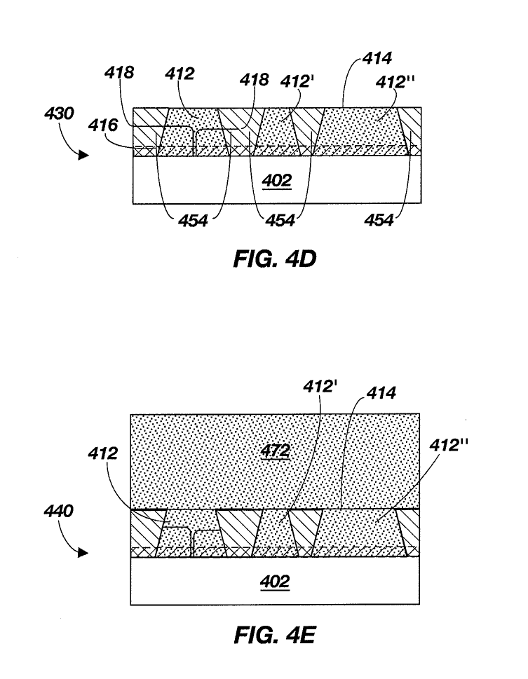

The embodiments of the invention are now described in greater detail with references to FIGS. 1A-F and further alternative embodiments of the invention are also described with reference to FIGS. 2A-G, FIGS. 3A-E and FIGS. 4A-E.

FIG. 1A illustrates intermediate structure 100 demonstrating an initial stage in embodiments of the invention. Intermediate structure 100 comprises a base substrate 102, a nucleation layer (NL) 104, and a plurality of crystal nuclei 106 formed thereon. The base structure can be composed of either a homogenous structure (i.e., a single material such as sapphire) or a heterogeneous structure (i.e., composed of multiple materials such as sapphire-on-silicon carbide). In certain embodiment of the invention, the average lattice parameter of the base substrate 102 is mismatched to the material grown upon the base substrate 102. For example, sapphire may be employed as the base substrate 102 and indium gallium nitride may be deposited upon the surface of the sapphire, and the sapphire and the InGaN materials may have different lattice parameters (e.g. different in-plane lattice parameters).

A plurality of nuclei 106 are formed upon base substrate 102. Epitaxial growth (and crystal growth generally) usually begins with the spontaneous formation of minute crystallites which serve as seeds for the growth of macroscopic crystals. The minute crystallites are referred to herein as “nuclei” and the processes of their formation and initial growth are referred to as “nucleation”. In the case of epitaxial growth, which nucleates on surfaces, the properties of the surface can strongly influence the spatial configurations and crystal properties of the nuclei by, for example, making certain configurations and properties more stable than other configurations and properties. The term nucleation layer refers to such surface properties whether achieved by deposition/growth of buffer layers, or by surface chemical treatments, or by other means.

Preferred nucleation layers promote InGaN (or other III-nitride) nucleation with nuclei having selected spatial density and configuration and having selected crystal properties. With respect to spatial density, these are selected in view of the subsequent application of isotropic growth and/or ELO techniques. In the case of ELO techniques, ELO is known in the art to produce substantially continuous and monocrystalline layers of III-nitrides of better quality if there are a sufficient number of growth sites available on which ELO can be initiated, and if the available growth sites are spaced apart so that lateral overgrowth from different growth sites can coalesce into a monocrystalline layer with minimal tilt/twist in the crystal growth fronts. Generally, it is preferred that NL 104 promotes nucleation in separate and isolated nuclei spaced apart on average a distance d between 0.1-100 μm, and, more particularly, between 0.2-3 μm, but may be otherwise randomly arranged, such as nucleation sites/nuclei 106 of intermediate structure 100 in FIG. 1A.

Numerous NL treatments (e.g., leading to NL 104 on base substrate 102) and their effects have been described and are known in the art and can be usefully utilized in this invention. See, e.g., Sumiya et al., 2004, Review of polarity determination and control of GaN, MRS Internet J. Nitride Semicond. Res. 9, 1; Gibart, 2004, Metal organic vapor phase epitaxy of GaN and lateral overgrowth, Rep. Prog. Phys. 67, 1; Dwikusuma et al., 2003, X-ray photoelectron spectroscopic study of sapphire nitridation for GaN growth by hydride vapor phase epitaxy: Nitridation mechanism, J of Appl. Phys. 94, 5656; Narayanan et al., 2002, Gallium nitride epitaxy on (0001) sapphire, Phil. Mag. A 82, 885, Stutzmann, et al., 2001, Playing with Polarity, phys. stat. sol. (b) 228, 505; Oh et al., 2006, Optical properties of GaN and GaMnN nanowires grown on sapphire substrates and Kikuchi et al., 2004, InGaN/GaN Multiple Quantum Disk Nanocolumn Light-Emitting Diodes Grown on (111) Si Substrate.

Having a base substrate 102 with a preferred NL 104 selected as described above, the methods of the invention next grow on the base substrate 102 InGaN island structures. First, nucleation conditions are selected, if necessary in view of the NL 104, so that InGaN (or other III-nitride) initially grows at nuclei 106 which have the spatial density and configuration described above. Generally, the density and configuration of nuclei 106 is such that a subsequent further growth produces the intended InGaN (or other III-nitride) layers (e.g., having preferred characteristics, such as, for example, reduced strain).

Growth conditions are selected, on average, to favor the growth of III-nitride island structures originating from the nuclei 106 of the NL 104 with the island structures remaining, on the whole, separated from one another and with a substantially random arrangement. FIG. 1B illustrates non-limiting intermediate structure 110 formed by the initially-grown InGaN on NL 104 on substrate 102. FIG. 3 is a scanning electron micrograph (SEM) image which presents an actual example corresponding to FIG. 1B.

The initial island structures have a trapezoidal-like structure 112 with flat upper surfaces 114. In the illustrated embodiment (see FIG. 1B), the island structures have grown into structures having, on average, horizontal dimensions approximately 1-2 times their vertical dimensions. In other embodiments, there can be relatively more vertical growth so that the island structures largely appear as pillars with more of a vertical configuration. In such embodiments, the vertical/lateral aspect ratio can be greater (e.g., approximately 2 or approximately 4). The invention also includes embodiments with more pronounced lateral growth so that the vertical/lateral aspect ratio is less than 1, but still results, on average, in separated island growth.

Growth conditions, in particular, the duration of growth, are further selected so that the upper portions of the island structures have progressively reduced strain. Growth is continued until the majority of the island structures have reduced levels of strain, preferably the majority of the island structures are strain-free (i.e., strain-relaxed). FIG. 1B illustrates enclosed dashed areas 116. Dashed areas 116 schematically represent the regions of the island structures in which strain relaxation occurs. In other words, the regions within the dashed areas 116 are regions in which defects (e.g., misfit dislocations) may form to alleviate the lattice mismatch between the island structures 112 and the base substrate 102.

In regions above enclosed area 116 the island structures are substantially free of strain or substantially strain-relaxed. The growth period is therefore controlled such that the strain due to lattice mismatch between the island structures and the base substrate 102 is rapidly relieved by, for example, the formation of defects such as misfit dislocations. On the other hand, growth should not be so long that island structures tend to merge together and no longer remain separate and isolated.

Typically, growth to a vertical island height of approximately 30 nm-1.5 μm is suitable. In certain embodiments, the island structures have a height greater than 30 nm. In additional embodiments, the island structures have a height greater than 150 nm. In yet further embodiments, the island structures have a height greater than 300 nm. In addition, the material composition of the island structures may comprise InₓGa₁₋ₓN, wherein the indium content is greater than x=0.02, or is greater than x=0.05, or is greater than x=0.08.

In addition to the formation of defects and dislocations in the regions proximate the interface between island structures 112 and the base substrate 102, further defects and dislocations can propagate from regions 116 into the body of the island structures. In the embodiment schematically illustrated in FIG. 1B, the island structures have been grown under such conditions so that dislocations 118 have bent laterally and terminated at a lateral side of the island structures. The upper portion 120 of the left hand island in FIG. 1B has therefore become relatively free of defects and dislocations and has a selected density of defects and dislocations. Such methods for additionally reducing the defect and dislocation density of the upper portion of the island structures are described in U.S. Application Ser. No. 60/952,131, which is fully incorporated by reference herein.

Conditions favoring either vertical or lateral growth are known and described in the art for the common VPE processes, such as, for example, the MBE, MOCVD, or HVPE processes. See, e.g., U.S. Pat. No. 6,325,850; see also Phys. Stats. Sol (c) 3, No. 6 1750-1753 (2006). Generally, the relative rates of lateral versus vertical growth are known to be influenced by growth temperature, V/III precursor ratio in the process gases, composition of the carrier gas (H₂ or N₂, or a combination thereof), and reactor pressure. For example, lateral growth is enhanced by higher growing temperatures, or by an increased VIII ratio, or by a greater N₂/H₂ ratio, or by lower pressures (less than or about 1 atm.), or by a combination thereof. Vertical growth is enhanced by the converse conditions. In particular embodiments, it can be advantageous to select details of NL treatment and of growing conditions in view of the strain in the InGaN island structures. To this end, strain properties of the initial InGaN island structures can be measured by means known in the art, such as, for example, transmission electron microscopy, and electron and/or x-ray diffraction.

Upon growth of the InGaN (or other III-nitride) island structures with upper portions having reduced strain or strain-relaxed levels, subsequent process steps may utilize the island structures directly as seed crystals for further growth to produce a continuous layer of semiconductor material. Further growth may therefore be continued from the island structures in an isotropic manner (i.e., a substantial uniform growth from all crystal facets) until such time as the island structures coalesce to from a substantially continuous layer.

Upon coalescence, the growth mode of the semiconductor layer can be altered to grow more preferentially in a vertical direction. In additional embodiments, the surface of the isotropically grown layer and/or the high quality substantially continuous semiconductor layer produced may require smoothing to remove any residual surface roughness from the layer to enable subsequent processing, such as device formation, layer transfer, etc. Smoothing of the layer can be achieved via etching, mass transport regrowth, polishing methods, grinding methods, etc.

FIG. 1C schematically illustrates intermediate structure 120 which demonstrates the initial stages of further growth from island structure 112. In this schematic illustration, the initial position of island structure 112, prior to additional growth, is designated by the dashed line 112. Further growth may continue in an isotropic manner, producing substantially isotropic material 122 or isotropic growth regions.

Embodiments of the invention may employ isotropic growth from the island structures 112, as the material employed for the isotropic growth is commonly unable to grow in a substantially lateral growth direction. for example InₓGa₁₋ₓN with an indium composition greater than x=0.11 has proven an exceedingly complex material in which to produce substantially lateral growth, (i.e., it is difficult to control the extent of the lateral growth relative to the extent of vertical growth). Therefore, in certain particular embodiments, the isotropically grown material has substantially the same material composition as that comprising the island structures 112. Therefore in certain embodiments of the invention, the island structures 112 comprise InₓGa₁₋ₓN with an indium composition greater than x=0.02 and the additional isotropic material or regions grown from the island structures likewise comprises InₓGa₁₋ₓN with an indium composition greater than x=0.02. As a result, continued further growth from the island structures does not introduce additional strain into the isotropic material 122.

However, as further isotropic growth of III-nitride material nucleates from all or nearly all of the exposed facets of the island structures, the lower regions in which defects and strain may remain are additionally used for nucleation. Therefore, regions 116 in which strain and defects may be present (e.g., such as misfit segments) can propagate further into the additional isotropic material 122.

In addition to the isotropic material growth effects on strain and defects in regions 116, it should also be noted that the isotropic growth may well effect defects dislocation 118, possibly resulting in the bending of such defects (e.g., dislocations). Since the material may grow in an isotropic manner, such defects may bend in a manner detrimental to the final quality of the final substantially continuous layer of material.

FIG. 1D schematically illustrates intermediate structure 130 which demonstrates the semiconductor structure upon the growth of further isotropic material 122′, and illustrates the growth upon the coalescence of the island structures to form a substantially continuous layer of semiconductor material.

In further detail, further growth of isotropic material 122′ is epitaxially grown from isotropic material 122 of intermediate structure 120. The growth of the further isotropic material results in the coalescence of island structures 112. Since the growth may be continued in a substantially isotropic manner, the surface topography of the original island structures 112 is generally maintained in the additional semiconductor material growth 122 and 122′. Since the topography is somewhat unchanged during the isotropic growth mode, grooves 134 are formed in the upper exposed surface of intermediate structure 130. Such grooves are undesirable for subsequent processing stages, whether subsequent processing stages are for the formation of device structures, or transfer of portions of semiconductor material, etc. Therefore, subsequent processes of the embodiments of the invention may include the removal of portions of the isotropic material to provide a smooth and substantially flat surface more suitable for subsequent processes.

FIG. 1E schematically illustrates intermediate structure 140, which demonstrates the processing of intermediate structure 130 to produce intermediate structure 140 which includes smooth upper surface 142.

In further detail, intermediate structure 130 is processed in such a way so as to remove grooves (i.e., pits, undulations, cavities, etc.) 134 from surface 136 to provide intermediate structure 140 with smooth upper surface 142. The smoothing of surface 136 to produce smooth upper surface 142 can be produced by a number of methods known in the art, including wet chemical etching, plasma etching (RIE, ICP, ECR, etc.), grinding, polishing, etc. Due to the topography of surface 136, an anisotropic etching method may be used to produce smooth surface 142, since material above the apex of grooves 136 will require extensive removal whilst material below the apex of grooves 136 is preferentially not removed to enable the planarization of the surface of the isotropic material 122.

In certain embodiments, the planarization of surface 136 to produce smooth surface 142 is performed utilizing grinding and/or polishing methods. In embodiments of the invention the planarization process is produced via a chemical mechanical polishing process (CMP). Sufficient isotropic material 122 is then removed by CMP using suitably selected slurry (e.g., having selected abrasives and slurry chemistry), and using suitable polishing parameters (e.g., applied pressures and speeds). Upon completion of the CMP process to produce surface 142, the surface roughness of surface 142 may be less 5 nm, less than 2 nm, or even less than 1 nm. In alternative embodiments, the CMP process may be performed upon regrowth in a more vertical growth direction on the isotropically grown material.

It should be noted that defects, such as the dislocation 118, may change their propagation direction during the embodiments of the invention resulting in such defects, such as the dislocation 118, being present at surface 142 in detriment to the quality of surface 142.

Intermediate structure 140 (of FIG. 1E) provides a highly suitable template structure for the growth of further III-nitride materials (e.g., for high quality substantially continuous strain-relaxed InGaN). In certain embodiments, intermediate structure 140 is utilized for the growth of InGaN with an indium composition substantially equal to that of the underlying isotropic material, whereas in other embodiments, intermediate structure 140 is utilized for the growth of InGaN with greater indium content than that of the isotropic material.

FIG. 1F illustrates structure 150 demonstrating the growth of a further layer on intermediate structure 140 of FIG. 1E. In certain embodiments of the invention, further layer 152 is grown in a more vertical mode, thereby forming a vertical growth layer, which promotes the thickening of the semiconductor material to a desired thickness. The vertical growth layer is grown, as is known in the art, with a preferential vertical growth mode by variation in epitaxial growth parameters. As previously noted, the vertical growth layer may be smoothed upon completion via previously mentioned methods utilizing CMP. Therefore, the planarization of the vertical growth layer of these embodiments can be performed prior to and/or after the epitaxial growth of the vertical growth layer. It should also be noted that example dislocation 118 formed during the formation of the island structures is illustrated as propagating into and to the surface of vertical growth layer 152.

The vertical growth layer, in certain embodiments, comprises an InₓGa₁₋ₓN layer with indium content substantially equal to that of the underlying island structures and isotropic material. More specifically, the vertical growth layer may comprise InₓGa₁₋ₓN material with an indium composition of greater than x=0.02, or greater than x=0.05, or greater than x=0.08.

Therefore, embodiments of the invention may be capable of producing a continuous layer of strain-relaxed, substantially single compositional phase InGaN with a preferred defect (e.g., dislocation) density. The thickness of the resulting layer 152 can be less than approximately 1 μm, less than approximately 100 μm, less than approximately 500 μm, or less than approximately 1000 μm.

Resulting continuous vertical growth layer 152 may be employed for the fabrication of electronic components, photovoltaic components, optic components, or opto-electronic components, etc. In alternative embodiments of the invention, either a portion or the entire continuous semiconductor layer can be transferred from intermediate structure 150 for producing free standing or composite type substrates. Transfer processes can proceed with detachment of a portion of the continuous layer and may also include bonding techniques.

In certain embodiments, a portion of semiconductor layer 152 can be detached from intermediate structure 150 through ion implantation and separation techniques, such as, for example, those techniques referred to in the art as SMART-CUT® techniques. Such processes are described in detail in, for example, U.S. Pat. No. RE39,484 to Bruel, U.S. Pat. No. 6,303,468 to Aspar et al., U.S. Pat. No. 6,335,258 to Aspar et al., U.S. Pat. No. 6,756,286 to Moriceau et al., U.S. Pat. No. 6,809,044 to Aspar et al., and U.S. Pat. No. 6,946,365 to Aspar et al., the disclosures of each of which are incorporated herein in their entirety by this reference.

Alternative embodiments of the invention are now described with reference to FIGS. 2A-G. Many elements of the alternative embodiments of the invention are equivalent to those previously described, and the subsequent description concentrates principally on the different characteristics of the alternative embodiments.

Briefly, alternative embodiments of the invention utilize the majority of the methods previously described, but utilize the formation of a masking structure to mask certain portions of the island structures. Therefore, nucleation of further growth from the island structures can be limited to the high quality crystal portions of the island structures. In addition, further growth from the island structures is promoted in a more lateral direction, for example utilizing methods such as ELO.

In more detail, FIG. 2A is similar to FIG. 1A and illustrates intermediate structure 200, which demonstrates the formation of NL 204 on base substrate 202 and the formation of nuclei 206 with a preferred spacing d. FIG. 2B is similar to FIG. 1B and illustrates intermediate structure 210, which demonstrates the formation of InGaN island structures 212 with preferred crystal characteristics (i.e., having an upper surface 214 with reduced lattice strain or strain-relaxed).

Upon growth of the InGaN (or other III-nitride) island structures with upper portions having reduced strain or strain-relaxed levels, subsequent process steps cover the exposed portions of the base substrate that are not covered by the island structures with a masking material forming a masking structure. The masking structure has a thickness (or depth) sufficient to cover most or all of the lower portions of the island structures where strain may still be present and in addition lateral faces with relatively larger numbers of terminating defects (e.g., dislocations). However, the masking structure may not cover the upper portions of the island structures where the faces have reduced strain levels or relaxed strain levels and only a relatively smaller number of terminating defects (e.g., dislocations).

Additionally, upper portions of the island structures that emerge through the masking structure can have sloping facets sufficient to promote subsequent ELO growth starting on the emergent upper portions of the island structures and then extending across the mask.

Preferred masking materials for forming the masking structure are those on which GaN (or other III-nitride such as low indium content InGaN) does not readily nucleate. Such materials include silicon oxides, silicon nitrides, combinations thereof (e.g., silicon oxy-nitride), and other refractory silicon-containing materials. Silicon nitrides may be relatively more easily removed by processes such as chemical mechanical polishing (CMP) than is InGaN. It should also be noted that a combination of masking materials could also be utilized such as silicon oxide/nitride layer stack(s), such a combination of masking materials may be employed to assist in controlled removal of portions of the masking structure.

FIG. 2C schematically illustrates intermediate structure 230, which exemplifies embodiments for mask structure formation comprising depositing masking material to fully cover the island structures. FIG. 2D illustrates intermediate structure 240, which exemplifies the subsequent removal of sufficient masking material so that the uppermost portions of the island structures emerge through the mask.

Accordingly, a masking material 232 is first formed by, for example, spin-on-glass processes or chemical vapor deposition (CVD) processes, so that the island structures are fully covered as illustrated in FIG. 2C. Here, island structures 212 (on base substrate 202) have been completely covered by masking material 232. In certain embodiments of the invention, the masking materials are deposited by CVD processes under real time monitoring control so that deposition can be halted when the mask has reached a preferred thickness range. For example, during deposition, the substrate can be scanned by radiation capable of detecting surface features (e.g., size of surface irregularities) that provide feedback concerning the height of the InGaN pillars that remain emergent above the thickening mask. Such radiation can be visible, IR or UV light, or particles (as in SEM).

Subsequently, a top portion of the masking material is removed or detached by, for example, etching techniques such as wet chemical etching, plasma etching (reactive ion etching, inductively coupled plasma etching, etc.) or by polishing techniques such as chemical-mechanical polishing (CMP), so that the final mask thickness is in a preferred range to promote subsequent epitaxial lateral overgrowth.

FIG. 2D illustrates intermediate structure 240, which comprises intermediate structure 230 after removal of a portion of masking material 232. A preferred amount of masking material has been removed so that the mask layer has a thickness in a desirable range. In such a desirable range, the upper faces of the island structures 214 are exposed, but the majority of side facets 242, strained regions 216 and dislocations 218 of the island structures remain covered to prevent subsequent further growth from nucleating from these regions, therefore improving subsequent crystal quality. Generally, a thickness range for the height of the mask may be approximately 60-90% of the height of the island structures.

Since little or no InGaN (or other III-nitride material) should be removed along with the masking material, desirable masking materials also have characteristics that promote their more rapid removal as compared to the removal of InGaN. For example, when masking material is to be removed by CMP, it should be more easily abraded or etched than is InGaN (which is known to be relatively hard and resistant to removal by CMP).

In more detail, silicon nitride can be deposited to fully cover the island structures by a CVD process (e.g., from gaseous SiH₄ and NH₃) under conditions known in the art. Sufficient masking material is then removed by CMP using suitably selected slurry (e.g., having selected abrasives and slurry chemistry), and using suitable polishing parameters (e.g., applied pressures and speeds).

Briefly, slurry abrasives, polishing pressures, and the like are selected so that silicon nitride is removed primarily by mechanical action down to the top of the InGaN pillars, which are left relatively unaffected. Slurry chemistry, pH, and the like are selected to promote the corrosion, dissolution, and dishing out of silicon nitride between the InGaN pillars so that their uppermost portions are emergent through the remaining masking material. Optionally, masking material detachment can be monitored in real time so that CMP can be halted after a preferred thickness range has been reached. Also, a cleaning treatment can follow CMP in order to remove residual slurry.

In an ideal case, the CMP process should result in little or no roughening of the surface of the InGaN island structures. However, if the abrasive action of the CMP process results in the abrasion of the InGaN surface, then the layer may be smoothed or planarized using, for example, a CMP process. In the case of III-nitrides, the roughened surface can be smoothed by mass transport regrowth methods know in the art.

In embodiment of the invention, the sample is heated in an NH₃+H₂ atmosphere to a temperature that promotes mass transport regrowth. During mass transport regrowth, the high energy peaks in the material are redistributed into the valleys of the material, thereby resulting in a smoothing action and a surface more suitable for subsequent ELO. See, e.g., Japanese Journal of Applied Physics Part 1 40 565 (2001) and Applied Surface Sciences 159-160 421 (2000).

In addition, the largely separated InGaN island structures may require supplementary smoothing to produce a unified pillar height. The pillar height uniformity may be important when subsequent processing requires the removal of masking material and the ability to stop mask removal once the III-nitride material has been revealed. An uneven pillar height could result in inefficient mask removal and a non-ideal surface for producing the lateral growth layer. For III-nitrides, the uneven surface can be smoothed by the mass transport regrowth methods described in the previous paragraph.

In subsequent stages of embodiments of the invention, the upper exposed portions of the InGaN island structures with preferred crystal characteristics (i.e., substantially strain-relaxed as well as a desirable defect (e.g., dislocation) density and a single compositional phase) are utilized as seed crystals for further material growth.

The upper portions of the InGaN island structures are utilized as seed crystals for lateral growth of lateral growth regions. However, high indium content lateral growth layers (e.g., with an indium content greater than 11%) have proven complex to produce and reports of such layers are unknown in the prior art at this time. Therefore, the lateral growth regions comprise a material that is capable of growing primarily in a lateral direction. As a non-limiting example, GaN (or low indium content InGaN) can be utilized to form the lateral growth regions and/or a possible lateral growth layer. However, since the laterally grown GaN regions (layer) are strained to the underlying relaxed InGaN island structures, the lateral growth regions (layer) will maintain the lattice constant of a higher indium content InGaN.

Accordingly, embodiments of the invention utilize the relaxed upper surface of the InGaN island structures as nucleation seeds for a further growth of GaN (or low percentage indium content InGaN) lateral layer. Since GaN is known in the art as being capable of lateral growth (see, for example, U.S. Pat. Nos. 6,015,979 issued January 12^{th} to Sugiura, 6,051,849 issued Apr. 18, 2000 to Davis and 6,153,010 issued Nov. 28, 2000 to Kiyoku), a substantially continuous layer of GaN material can be produced above the separated, relaxed upper portions of the InGaN island structures.

The thickness of the GaN lateral growth regions and subsequent lateral growth layer can be maintained below the critical thickness for on-set of strain relaxation through the formation of defects and dislocations. In such cases the relaxed InGaN strain-relaxed lattice parameter of the upper portions of the island structure is substantially maintained in the GaN lateral growth layer. In other words, the in-plane lattice parameter of the GaN lateral growth regions (layer) substantially equals that of the underlying relaxed InGaN island structures. In addition, since strain is not alleviated through the formation of additional defects (e.g., dislocations) in the GaN lateral regions (layer), the defect (e.g., dislocation) density of the high quality InGaN pillar upper surfaces is substantially maintained in the GaN lateral regions (layer).

Therefore, methods of the invention produce a template structure which comprises an upper continuous surface which has an in-plane lattice parameter substantially equal to the underlying InGaN island structures, whilst maintaining a preferred defect (e.g., dislocation) density. Such a template structure of semiconductor material with preferred material characteristics is highly suitable for the growth of further high quality InGaN material with substantially similar or increased indium content in comparison to the InGaN island structures.

In greater detail, FIG. 2E illustrates intermediate structure 250 which demonstrates the initial stages of the further growth producing lateral growth of the lateral growth regions, which comprise, for example, GaN. As previously discussed, methods are known in the art for controlling the extent of lateral versus vertical growth of GaN (or low indium content InGaN).

In certain embodiments, the growth can be initiated from upper exposed portions of the island structures 214 in a more vertical growth mode, and, upon obtaining a desired vertical height, switched to a more lateral growth mode. Alternatively, a lateral growth mode can be utilized from the start. In certain embodiments, an initial vertical growth mode may be employed to provide side facets 252 from which lateral growth can be initiated. In addition, growth conditions can be selected to yield a growth mode incorporating both lateral and vertical components. Conditions suitable for obtaining vertical and lateral growth modes are known in the art.

In further detail, FIG. 2E illustrates an early stage in the lateral growth from upper portions of island structure 214. The GaN lateral growth regions 254 originate or nucleate from upper island surfaces 214 producing lateral crystal growth fronts 252. The GaN lateral growth regions deposited during the lateral growth process can be expected to inherit properties (defect density, lattice parameter) of the material on which it nucleates, as previously mentioned. The thickness of the GaN lateral growth regions 154 d is maintained at or below the critical thickness as previously outlined. The thickness d for the onset of strain relaxation by defect formation is a function of the growth method as well as the composition of the underlying InGaN material. In certain embodiments, the critical thickness of the GaN lateral regions is less than 500 nm, in further embodiments, less than 250 nm, and in yet further embodiments, less than 100 nm. In certain embodiments, the lateral growth regions comprise InₓGa₁₋ₓN having an indium content of less than x=0.11, less than x=0.08, or even less than x=0.05.

FIG. 2F illustrates intermediate structure 260 in which the lateral growth process is at the stage of coalescence of GaN lateral growth regions to form lateral growth layer 254, to form a substantially continuous film of III-nitride material. Semiconductor growth fronts 252 (of intermediate structure 250 of FIG. 1E) converge and merge together to form a single coalesced film of lateral growth material (e.g., GaN, or low indium content InGaN). The spatial arrangement, size and structure of the upper surfaces of InGaN island structures 212 are preferably optimized such as to promote a high quality lateral growth process (as previously discussed) (e.g., distributed and spaced such as to prevent crystal tilt/twist prior to coalescence), thereby substantially preventing further defect formation. For example, central island 212′ and right island 212″ structures produce lateral growth fronts which coalesce without producing a further defect (e.g., dislocation). However, central island 212′ and left island 212 produce lateral growth fronts which coalesce to produce defect (e.g., dislocation) 262 due to the non-ideal distribution and spacing of the two seeding island structures.

Therefore, intermediate structure 260 (of FIG. 2F) provides a highly suitable template structure for the growth of further III-nitride materials (e.g., for high quality substantially continuous strain-relaxed InGaN). In certain embodiments, intermediate structure 260 is utilized for the growth of InGaN with an indium composition substantially equal to that of the underlying island structures. In additional embodiments, intermediate structure 260 is utilized for the growth of InGaN with greater indium content than that of the island structures.

FIG. 2G illustrates structure 270, which demonstrates the growth of an additional layer on intermediate structure 260 of FIG. 2F. In certain embodiments of the invention, additional layer 272 is grown in a more vertical mode, thereby forming a vertical growth layer, which promotes the thickening of the semiconductor material to a desired thickness. The vertical growth layer is grown, as is known in the art, with a preferential vertical growth mode by variation in epitaxial growth parameters. It should be noted that the example dislocation 262 defect shown in FIG. 2G, which may be formed during the coalescence of lateral growth layer 254, is illustrated as propagating into and to the surface of vertical growth layer 272.

The vertical growth layer, in certain embodiments, comprises an InGaN layer with indium content substantially equal to that of the underlying island structures. Therefore, embodiments of the invention are capable of producing a continuous layer of strain-relaxed, substantially single compositional phase InGaN with a preferred defect (e.g., dislocation) density. The thickness of the resulting layer 272 can be approximately 1 μm or less, 1 approximately 100 μm or less, approximately 500 μM or less, or even approximately 1000 μM or less.

Resulting continuous vertical growth layer 272 may be employed for the fabrication of electronic components, photovoltaic components, optic components, opto-electronic components, etc. In alternative embodiments of the invention, either a portion or the entire continuous semiconductor layer can be transferred from intermediate structure 270 for producing free standing or composite type substrates. Transfer processes can proceed with detachment of a portion of the continuous layer and may also include bonding techniques.

In certain embodiments, a portion of semiconductor layer 272 can be detached from intermediate structure 270 through ion implantation and separation techniques using, for example, techniques referred to in the art as SMART-CUT® processes, and references disclosing such processes have been previously mentioned.

Alternative embodiments of the invention are now described with reference to FIGS. 3A-E. Many elements of the alternative embodiments of the invention are equivalent to those previously described. Therefore, the subsequent description will concentrate principally on the novel characteristics of the alternative embodiments.

Briefly, alternative embodiments of the invention utilize the majority of the methods previously described but with the omission of the formation of the masking structure and the associated processes required to produce such a masking structure. Masking layer omission can simplify the processes of the embodiments of the invention without sacrificing the quality of the final product (i.e., high quality strain-relaxed continuous semiconductor materials such as, for example, InGaN).

In more detail, FIG. 3A is equivalent to FIG. 1A and illustrates intermediate structure 300 which demonstrates the formation of NL 304 on base substrate 302 and the formation of nuclei 306 with a preferred spacing d. FIG. 3B is equivalent to FIG. 1B and illustrates intermediate structure 310 which demonstrates the formation of InGaN island structures 312 with preferred crystal characteristics, i.e., having an upper surface 314 with reduced lattice strain or strain-relaxed.

FIG. 3C illustrates intermediate structure 350 demonstrating the initial stages of lateral growth utilizing for example GaN as lateral growth regions 354 producing lateral growth fronts 352. As previously noted, in alternative embodiments of the invention, the masking structure is omitted. Therefore, lateral growth is initiated from upper surfaces 314 of the InGaN island structures, and lateral growth from island side facets 342 is inhibited. Methods for controlling growth from different facets of a crystal structure are known in the art. For example, facet selective nucleation of the nitrides from nano-scale features (e.g., island structures) have been reported in the literature (see for example Lee et al Journal of Crystal Growth, 279 289 2005). In certain embodiments, the lateral growth regions comprise InₓGa₁₋ₓN with an indium content of less than x=0.11, less than x=0.08, or even less than x=0.05.

It should be noted that, although the lateral growth regions originate extensively from the upper surfaces of the semiconductor island structures, in reality, a degree of deposition on other surfaces of the semiconductor island structures intermediate structure 350 of FIG. 3C may occur due to the lack of a masking material to conceal the additional surfaces of the semiconductor island structures.

Alternative embodiments of the invention then continue as previously described. FIG. 3D illustrates intermediate structure 360, which demonstrates the coalescence of the individual growth lateral fronts of lateral growth regions to form a substantially continuous lateral growth layer 354, comprising defect 362. Further FIG. 3E illustrates structure 370 which demonstrates the addition of vertical growth layer 372 to intermediate growth structure 360 by employing a more vertical growth mode to epitaxially grow a layer of vertical growth mode material to a desired thickness. The vertical layer 372 may be of improved quality due to the nature of the surface of the InGaN island structures and the inheritance of these properties by the lateral growth layer.

Resulting continuous vertical growth layer 372 may be employed for the fabrication of electronic components, photovoltaic components, optic components, opto-electronic components, etc. In alternative embodiments of the invention, either a portion or the entire continuous semiconductor layer can be transferred from intermediate structure 370 for producing free standing or composite type substrates. Transfer processes can proceed with detachment of a portion of the continuous layer and may also include bonding techniques.

In certain embodiments, a portion of semiconductor layer 372 can be detached from intermediate structure 370 through ion implantation and separation techniques using, for example, techniques referred to in the art as SMART-CUT® processes. References describing such processes have been previously mentioned.

Further, alternative embodiments of the invention are now described with reference to FIGS. 4A-E. Many elements of the alternative embodiments of the invention are equivalent to those previously described. Therefore, the subsequent description will concentrate principally on the differences in the alternative embodiments.

Briefly, alternative embodiments of the invention utilize the majority of the methods previously described but with the omission of the formation of the masking structure and the associated processes required to produce such a masking structure. However, in these alternative embodiments, lateral overgrowth nucleates extensively from the side facets of the island structures forming lateral growth regions between the island structures. These alternative embodiments of the invention, therefore, produce an intermediate structure comprising an upper surface comprising relaxed island structures interposed between strained lateral growth regions. Consequently, a substantial portion of the upper surface of the intermediate structure possesses an in-plane lattice parameter equal to that of the upper portions of the relaxed island structures.

In more detail, FIG. 4A is similar to FIG. 1A and illustrates intermediate structure 400 which demonstrates the formation of NL 404 on base substrate 402 and the formation of nuclei 406 with a preferred spacing d. FIG. 4B is similar to FIG. 1B and illustrates intermediate structure 410 which demonstrates the formation of InGaN island structure 412 with preferred crystal characteristics, i.e., having an upper surface 414 with reduced lattice strain or strain-relaxed.

FIG. 4C schematically illustrates intermediate structure 420 which exemplifies an early stage of lateral growth wherein lateral growth nucleates extensively from side facets 442 (and their equivalents) of island structures 412. In more detail, methods are known in the art for producing substantially more lateral growth as opposed to vertical growth from the side facets of the island structures, as previously outlined. Lateral growth regions 454 therefore originate from side facets 442 and expand laterally as the growth process continues.

As previously mentioned, in certain embodiments, the lateral growth material used to produce lateral growth regions 454 can be capable of growth in a more lateral mode as opposed to a vertical growth mode Such a material may comprise, for example, GaN and/or low indium content InₓGa₁₋ₓN (e.g., x<0.05). In certain embodiments the lateral growth regions comprise InₓGa₁₋ₓN with an indium content of less than x=0.11, less than x=0.08, or even less than x=0.05. As outlined in previous embodiments, the lateral growth regions may be grown to a thickness less than that or equal to that of the critical thickness, such that the lateral growth regions maintain the lattice parameter and strain characteristics of the island structures from which they nucleated. It would also be noted that, since the lateral growth regions nucleate extensively from the surface of side facts 424 of the island structures 412, nucleation will also initiate from regions 416 (i.e., from regions in which levels of strain and defects may be undesirable).

FIG. 4D schematically illustrates intermediate structure 430, which demonstrates the formation of lateral growth regions at the stage of complete coalescence to form a continuous film comprising island structures 412 and lateral growth regions 454. Upper surface 414 of intermediate structure 430 therefore comprises the relaxed upper surface of InGaN island structures 412 and lateral growth regions 454. Since the lateral growth regions nucleate from island structure 412 and are maintained at a thickness at or below the critical thickness, the lateral growth regions will inherit both the lattice parameter and the strain level of the island side facets.

Intermediate structure 430 therefore comprises a template structure which is highly suitable for the growth of further high quality relaxed III-nitride materials such as InGaN. Therefore, FIG. 4E schematically illustrates intermediate structure 440 which demonstrates the growth of an additional vertical growth layer 472 from the surface 414 of intermediate structure 430. As in previous embodiments, the vertical growth layer can be grown to certain compositions and thicknesses as previously outlined and may be utilized for the formation of further structures or devices, or portions may be transferred for the fabrication of substrate structures using techniques previously outlined.

A number of examples are now described to further illustrate the embodiments of the invention. It should be understood that the in the following examples, physical parameters (e.g., times, temperatures etc.) are for illustrative purposes only and are not to be taken as limiting.

### EXAMPLES

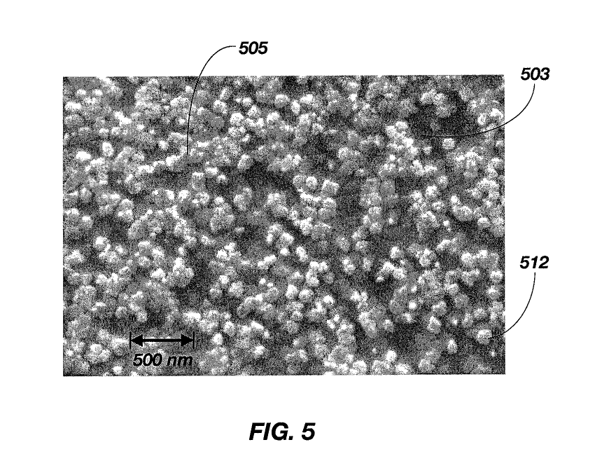

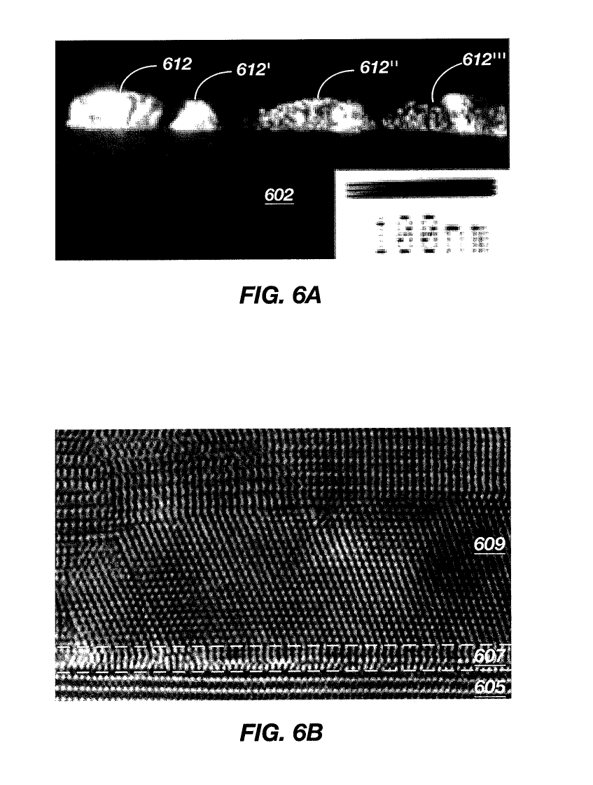

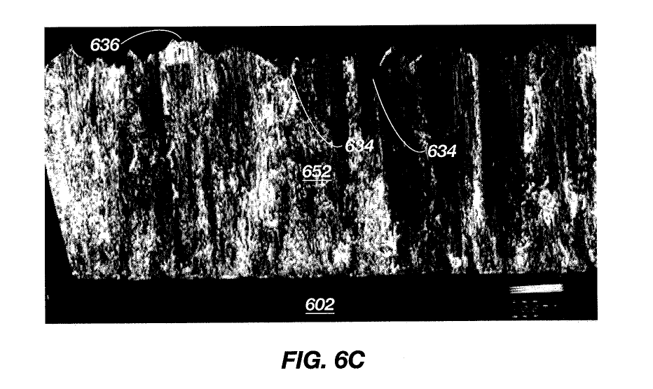

FIG. 5 illustrates a scanning electron microscopy (SEM) top view image and FIG. 6A-B illustrate transmission electron microscopy (TEM) side view images of actual examples of InGaN island structures formed on base substrates utilizing embodiments of the invention previously outlined. In particular, island structures 612, 612′ and 612″ (of FIG. 6A) correspond to those illustrated in the intermediate structure 110 in FIG. 1B. In addition, FIG. 6C illustrates a substantially continuous layer of strain-relaxed InGaN produced using embodiments of the invention.

The island structures of FIGS. 5 and 6A-B have been produced by the following means. Prior to deposition of the InGaN island structures, a sapphire substrate is heated within a MOVPE reactor to a temperature of between 600-900° C. In certain embodiments, the temperature is maintained at 750° C. whilst ammonia is introduced into the reaction chamber for 3-5 mins to enable the nitridation of the sapphire surface. Subsequently, the MOVPE reactor temperature is raised to between 800° C. and 1000° C. For example, the temperature may be maintained at 860° C. during the growth of the isolated InGaN features. The pressure range during the growth was maintained between 200 mbar to 400 mbar (i.e., the pressure was maintained at about 300 mbar). The ratio of V species (e.g., ammonia) to III species (e.g., Trimethylgallium, Trimethylindium) was kept low to promote 3-D pillar growth. VIII ratios utilized were between 500-2500 (e.g., about 1000).

FIG. 5 illustrates that the island structures are positioned more or less randomly with a maximum average spacing of about 250 nm. The island structures, or small groups thereof, are separated and isolated. Island 512 of FIG. 5 illustrates an example of an isolated, randomly arranged island structure. In addition, base substrate 502 (a sapphire substrate in this example) is clearly visible illustrating the boundary between island structures. Although most island structures are individually separated and isolated, a small number have grown together into groups of 2-3 pillars/island structures (e.g., group 505).

FIG. 6A illustrates a cross-section image produced by high resolution transmission electron microscopy (HR-TEM) of another example of a preferred base substrate 602 with a plurality of InGaN island structures 612, 612′, 612″ and 612′″, which have been produced as described above. In this example, island-like features 612, 612″ and 612′″ have greater horizontal dimensions compared to the vertical dimensions and are comparable to the island like features 112 and 112″ of intermediate structure 110 in FIG. 1B. Furthermore, island-like feature 612′ (FIG. 4A) has approximately equal horizontal and vertical dimensions and is comparable to island like feature 112′ in FIG. 1B. Generally the island structures are separated spatially with spacing highly suitable for subsequent lateral growth processes.

In addition, the island structures have approximately equal heights, in this example, on the order of 30 nm. Certain features have an approximately rectangular cross-section, and can be considered more pillar-like. Certain other features have an approximately triangular cross-section, and can be considered more pyramid-like. And further features have one or more sloping horizontal facets, and can be considered as truncated pyramids or as columns with pyramidal tops.

FIG. 6B illustrates a further high resolution HR-TEM image illustrating the initial stages of growth of the InGaN island structures. Region 605 corresponds to the base substrate, in this example, consisting of a sapphire substrate. The HR-TEM image clearly shows the well ordered crystalline structure of the sapphire substrate as observed by the ordered periodicity of the atomic structure. However, in region 607 above the base sapphire substrate (i.e., at initial stages of the InGaN island growth) the periodicity of the crystalline structure is somewhat disordered, for example, due to the formation of defects, such as misfit dislocation, and/or due to the lattice mismatch between the base substrate and the island structures (i.e., between the sapphire and the InGaN island structures).

Above somewhat disordered InGaN region 607 is situated region 609 where the well ordered periodicity is again observed indicating a return to a more order crystalline structures. Further analysis of region 609 indicates that the InGaN material is composed of In_{0.18}Ga_{0.82}N with a relaxed lattice parameter, indicating that the InGaN material of region 609 is suitable for subsequent lateral growth and continuous strain-relaxed semiconductor film formation.

FIG. 6C illustrates yet a further HR-TEM image illustrating the formation of a substantially continuous layer of strain-relaxed InGaN material produce through embodiments of the invention similar to those schematically illustrated in FIGS. 1 A-F. Base substrate 602 is clearly visible and, as in the previous examples, comprises a sapphire material. Above the sapphire base substrate is a continuous layer of strain-relaxed InGaN material 652, produced via the methods of initiating further growth from InGaN island structures 612 of FIG. 6A.

In this example the further growth is produce via substantially isotropic further growth from the island structures to produce a continuous layer with an approximate thickness of about 850 nm. As analogous to FIG. 1D the surface of the strain-relaxed InGaN layer 636 comprises grooved regions 634 where the topography of the initial islands structures from which the layer was seeded has been maintained. To produce a layer of strain-relaxed InGaN material suitable for further processing, surface 636 may require planarization, for example utilizing methods such as chemical mechanical polishing.

The preferred embodiments of the invention described above do not limit the scope of the invention, since these embodiments are illustrations of several aspects of the invention. Any equivalent embodiments are intended to be within the scope of this invention. Indeed, various modifications of the invention in addition to those shown and described herein, such as alternate useful combinations of the elements described, will become apparent to those skilled in the art from the subsequent description. Such modifications are also intended to fall within the scope of the appended claims. In the following (and in the application as a whole), headings and legends are used for clarity and convenience only.

What is claimed is:

1. A method for fabricating a semiconductor structure comprising:
forming a plurality of arranged island structures with a first material composition;
performing a further growth from the island structures, the composition of the further growth having a second material composition; and
performing a vertical growth to form a vertical growth layer, the composition of the vertical growth layer having a third material composition.

2. The method of claim 1, wherein the island structures comprise strain-relaxed regions.

3. The method of claim 1, wherein performing a further growth from the island structures comprises originating the further growth substantially from the strain-relaxed regions of the island structures.

4. The method of claim 1, wherein performing a further growth from the island structures comprises laterally growing the island structures to form lateral growth regions.

5. The method of claim 4, wherein laterally growing the island structures to form the lateral growth regions comprises originating the lateral growth substantially from an upper surface of the island structures.

6. The method of claim 4, wherein laterally growing the island structures to form the lateral growth regions comprises originating the lateral growth substantially from a side surface of the island structures.

7. The method of claim 1, wherein performing a further growth from the island structures comprises isotropically growing the island structures to form isotropic growth regions.

8. The method of claim 7, further comprising planarizing at least one of the isotropic growth regions and the vertical growth layer using a chemical mechanic polishing process.

9. The method of claim 1, wherein forming a plurality of arranged island structures further comprises epitaxially growing the island structures at random locations on a lattice mismatched base substrate.

10. The method of claim 9, further comprising providing a masking structure on the base substrate and exposing upper portions of the island structures through the masking structure.

11. The method of claim 4, further comprising maintaining a thickness of the lateral growth regions at or below a critical thickness of the lateral growth regions.

12. The method of claim 4, further comprising coalescing the lateral growth regions to form a substantially continuous lateral growth layer.

13. The method of claim 1, further comprising selecting the first material composition, the second material composition, and the third material composition to each comprise InₓGa₁₋ₓN.

14. The method of claim 1, further comprising selecting the second material composition to comprise GaN.

15. The method of claim 1, further comprising selecting the first material composition and the third material composition to be substantially identical.

16. The method of claim 1, further comprising forming the vertical growth layer to comprise a substantially continuous strain-relaxed layer.

17. The method of claim 10, wherein providing a masking structure on the base substrate comprises depositing at least one dielectric material and subsequently planarizing the at least one dielectric material to expose the upper portions of the island structures.

18. The method of claim 17, wherein planarizing the at least one dielectric material comprises at least one of chemical mechanical polishing the at least one dielectric material and/or plasma etching the at least one dielectric material.

19. A semiconductor structure comprising;
a plurality of laterally isolated island structures upon a lattice mismatched base substrate;
a plurality of further growth regions formed on the island structures; and
a vertical growth layer formed on at least one of the island structures and the further growth regions.

20. The structure of claim 19, wherein the laterally isolated island structures are substantially strain-relaxed.

21. The structure of claim 19, further comprising one or more dielectric masking materials substantially at least partially covering the exposed base substrate.

22. The structure of claim 19, wherein the further growth regions comprise lateral growth regions having thicknesses less than a critical thickness.

23. The structure of claim 22, wherein the lateral growth regions form a substantially continuous film having a thickness less than a critical thickness.

24. The structure of claim 19, wherein a material composition of the island structures comprises InₓGa₁₋ₓN having an indium composition greater than x=0.02.

25. The structure of claim 19, wherein the further growth regions comprise InₓGa₁₋ₓN having an indium composition less than x=0.11.

26. The method of claim 19, wherein the vertical growth layer comprises InₓGa₁₋ₓN having an indium composition greater than x=0.02.

27. The structure of claim 19, wherein the vertical growth layer comprises a strain-relaxed substantially continuous layer of InₓGa₁₋ₓN.
